(19) United States
(12) Patent Application Publication
(10) Pub. No.: US 2009/0137128 A1
(43) Pub. Date: May 28, 2009

(54) Substrate Processing Apparatus and Semiconductor Device Producing Method

(75) Inventors: Kenmei Ko, Toyama (JP); Rui Harada, Toyama (JP); Kazuyuki Toyada, Toyama (JP); Yuji Takebayashi, Toyama (JP); Takashi Koshimizu, Toyama (JP); Takeshi Itoh, Toyama (JP)

Correspondence Address: BIRCH STEWART KOLASCH & BIRCH, PO BOX 747, FALLS CHURCH, VA, 22040-0747, US

(73) Assignee: HITACHI KOKUSAI ELECTRIC INC., TOKYO (JP)

(21) Appl. No.: 11/887,350

(22) PCT Filed: Apr. 27, 2006
(86) PCT No.: PCT/JP2006/308893

§ 371 Date: Sep. 28, 2007

(30) Foreign Application Priority Data
Apr. 28, 2005 (JP) 2005 132706
Sep. 27, 2005 (JP) 2005 280164

(51) Int. Cl. H01L 21/30; H01L 21/3065; H01L 21/306

(52) U.S. Cl. 438/710; 118/723 R; 156/345.43; 204/298.02; 204/298.31; 438/758; 257/E21.218; 257/E21.215; 257/E21.211

(57) ABSTRACT

Disclosed is a substrate processing apparatus including: a reaction tube to accommodate at least one substrate; at least a pair of electrodes disposed outside the reaction tube; and a dielectric member, wherein a plasma generation region is formed at least in a space between an inner wall of the reaction tube and an outer circumferential edge of the substrate, the member includes a main face extending in a radial direction of the substrate and in a substantially entire circumferential direction of the substrate in a horizontal plane parallel to a main face of the substrate, and is disposed in an outer circumferential region of the substrate, and gas activated in the plasma generation region is supplied through a surface region of the main face of the member to the substrate.

### TECHNICAL FIELD

The present invention relates to a substrate processing apparatus and a semiconductor device producing method, and more particularly, to a plasma processing apparatus for subjecting a to-be processed body to a predetermined treatment utilizing plasma generated by high-frequency (RF) electric power, and to a semiconductor device producing method using the plasma processing apparatus.

### BACKGROUND ART

In production of semiconductor integrated circuits, plasma is utilized for ionizing or facilitating chemical reaction of processing gas in CVD, etching, ashing or sputtering process. The generation of plasma in semiconductor manufacturing apparatus includes various conventional methods such as a parallel plate type method, a high-frequency induction method, a helicon wave method, and an ECR method. According to the parallel plate type method, one of a pair of parallel plate electrodes is grounded and the other electrode is capacitive-coupled to a high-frequency power supply to generate plasma between both the electrodes. In the high-frequency induction method, high-frequency is applied to a spiral or swirl antenna to form a high-frequency electromagnetic field, and electrons flowing in the electromagnetic field are allowed to collide with neutral particles in gas to generate plasma. In the helicon wave method, special electromagnetic field (helicon wave) moving in parallel to a magnetic field is generated by an antenna having a special shape in a uniform magnetic field formed by a coil, and then Landau damping effect caused by the helicon wave is utilized to introduce, through a waveguide, micro wave having frequency (2.45 GHz) which is equal to cyclotron frequency of electron flow whose speed can be controlled. Thereby, a resonance phenomenon occurs, and electrons are allowed to absorb microwave power to generate plasma. There are different methods for treating a to-be processed body by using these plasma generating methods. One such method is a single wafer type method for processing to-be processed bodies one by one. The other method is batch type method for processing a plurality of to-be processed bodies at a time.

In the case of the batch type plasma processing apparatus, since electrodes are disposed on an outer circumference of a reaction tube, plasma is generated mainly in a space between the reaction tube and the to-be processed body, and plasma is diffused from an edge of the to-be processed body toward its center. Therefore, there arises a problem that the processing speed at an edge of the to-be processed body is extremely accelerated owing to influence of a factor having high energy and short lifetime, and the in-plane uniformity in process treatment is extremely deteriorated. This phenomenon more strongly appears under the condition that high-frequency output is increased and density of factors having high energy is high.

Hence, it is a main object of the present invention to solve a problem of nonuniformity in-plane treatment of plasma caused by the influence of plasma which is generated at an edge of a to-be processed body and which has high energy and short lifetime, and to provide a substrate processing apparatus and a semiconductor device producing method capable of uniformly carrying out the in-plane treatment of the to-be processed body.

### DISCLOSURE OF INVENTION

According to one aspect of the present invention, there is provided a substrate processing apparatus, comprising:

a reaction tube to accommodate at least one substrate; and

at least a pair of electrodes disposed outside the reaction tube, wherein

a plasma generation region is formed at least in a space between an inner wall of the reaction tube and an outer circumferential edge of the substrate,

a dielectric member having a main face extending in a radial direction of the substrate and in a substantially entire circumferential direction of the substrate in a horizontal plane parallel to a main face of the substrate is disposed in an outer circumferential region of the substrate, and

gas activated in the plasma generation region is supplied through a surface region of the main face of the member to the substrate.

According to another aspect of the present invention, there is provided a producing method of a semiconductor device using a substrate processing apparatus, comprising:

a reaction tube to accommodate at least one substrate;

at least a pair of electrodes disposed outside the reaction tube; and

a dielectric member having a main face extending in a radial direction of the substrate and in a substantially entire circumferential direction of the substrate in a horizontal plane parallel to a main face of the substrate, the member being disposed in an outer circumferential region of the substrate,

the producing method, comprising:

a step of generating plasma at least in a space between an inner wall of the reaction tube and an outer circumferential edge of the substrate;

a step of activating processing gas with the plasma;

a step of supplying the activated gas through a surface region of the main face of the member to the substrate; and

a step of subjecting the substrate to a desired processing using the processing gas which has been passed through the surface region.

### BRIEF DESCRIPTION OF DRAWINGS

FIG. 1 is a schematic diagram for explaining a processing furnace of a plasma processing apparatus according to a first embodiment and a second embodiment of the present invention;

FIG. 2 is a schematic vertical sectional view for explaining the processing furnace of the plasma processing apparatus of the first embodiment of the invention;

FIG. 3 is a schematic transverse sectional view for explaining the processing furnace of the plasma processing apparatus of the first embodiment and the second embodiment of the invention;

FIG. 4 is a schematic vertical sectional view for explaining the processing furnace of the plasma processing apparatus of the second embodiment of the invention;

FIG. 5 is a diagram showing an oxide film thickness distribution when an overlap amount between a semiconductor wafer and a ring-shaped dielectric 17 is 0 mm in the second embodiment of the invention;

FIG. 6 is a diagram showing the oxide film thickness distribution when the overlap amount between the semiconductor wafer and the ring-shaped dielectric 17 is 10 mm in the second embodiment of the invention;

FIG. 7 is a diagram showing the oxide film thickness distribution when the overlap amount between the semiconductor wafer and the ring-shaped dielectric 17 is 20 mm in the second embodiment of the invention;

FIG. 8 is a schematic perspective view for explaining the plasma processing apparatus of the first embodiment and second embodiment of the invention;

FIG. 9 is a schematic transverse sectional view of a distribution state of plasma when the ring-shaped dielectric 17 is provided;

FIG. 10 is a schematic vertical sectional view of a distribution state of plasma when the ring-shaped dielectric 17 is provided;

FIG. 11 is a schematic transverse sectional view of a distribution state of plasma when the ring-shaped dielectric 17 is not provided;

FIG. 12 is a schematic vertical sectional view of a distribution state of plasma when the ring-shaped dielectric 17 is not provided;

FIG. 13 is a diagram showing plasma densities of an edge and a center of a wafer when the ring-shaped dielectric 17 is not provided;

FIG. 14 is a diagram showing a film thickness distribution on a wafer when the ring-shaped dielectric 17 is not provided;

FIG. 15 is a diagram showing a film thickness of a wafer 8 in its radial direction when the ring-shaped dielectric 17 is not provided;

FIG. 16 is a diagram showing a state where a half ring is used and a quartz ring is provided on only a portion corresponding to half of a semiconductor wafer for checking an influence on a film thickness distribution which is varied depending upon absence or presence of the ring-shaped dielectric 17;

FIG. 17 is a diagram showing film thickness distributions when the ring is not used and when the half ring is used;

FIG. 18 is a diagram showing an improvement effect of the film thickness distribution by the quartz ring;

FIG. 19 is a schematic diagram for explaining a processing furnace of a plasma processing apparatus for comparison;

FIG. 20 is a schematic vertical sectional view for explaining the processing furnace of the plasma processing apparatus for comparison; and

FIG. 21 is a schematic transverse sectional view for explaining the processing furnace of the plasma processing apparatus for comparison.

### BEST MODE FOR CARRYING OUT THE INVENTION

According to one aspect of the preferred embodiments of the present invention, there is provided a substrate processing apparatus, comprising:

a reaction tube to accommodate at least one substrate; and

at least a pair of electrodes disposed outside the reaction tube, wherein

a plasma generation region is formed at least in a space between an inner wall of the reaction tube and an outer circumferential edge of the substrate,
a dielectric member having a main face extending in a radial direction of the substrate and in a substantially entire circumferential direction of the substrate in a horizontal plane parallel to a main face of the substrate is disposed in an outer circumferential region of the substrate, and

gas activated in the plasma generation region is supplied through a surface region of the main face of the member to the substrate.

Preferably, the member is a ring-shaped flat plate.

Preferably, the ring flat plate comprises quartz.

Preferably, the main face of the member and the main face of the substrate are disposed on different horizontal planes in a vertical direction with respect to the main face of the substrate.

Preferably, a plurality of substrates are to be accommodated in the reaction tube, the substrates are to be stacked such that main faces of the substrates overlap each other with a space therebetween in a vertical direction with respect to the main faces, and the member is to be located between adjacent substrates.

Preferably, at least a portion of the main face of the member extends toward a center side of the substrate from the outer circumferential edge of the substrate, and the portion of the main face of the member is overlapped with a portion of the substrate as viewed from the vertical direction.

Preferably, overlap between the main face of the member and the substrate in the vertical direction ranges from 0 to 50 mm in a radial direction of the substrate.

Preferably, adjacent substrates are stacked at a distance of 6 to 13 mm, and a width of the main face of the member in the radial direction of the substrate ranges from 10 to 40 mm.

According to another aspect of the preferred embodiments of the present invention, there is provided a producing method of a semiconductor device using a substrate processing apparatus, comprising:

a reaction tube to accommodate at least one substrate;

at least a pair of electrodes disposed outside the reaction tube; and

a dielectric member having a main face extending in a radial direction of the substrate and in a substantially entire circumferential direction of the substrate in a horizontal plane parallel to a main face of the substrate, the member being disposed in an outer circumferential region of the substrate,

the producing method, comprising:

a step of generating plasma at least in a space between an inner wall of the reaction tube and an outer circumferential edge of the substrate;

a step of activating processing gas with the plasma;

a step of supplying the activated gas through a surface region of the main face of the member to the substrate; and

a step of subjecting the substrate to a desired processing using the processing gas which has been passed through the surface region.

### FIRST EMBODIMENT

In the first embodiment of the present invention, an obstruction including a ring-shaped dielectric having a 10 to 40 mm width is formed on an outer circumference of a to-be processed body. With this, plasma having high energy at an edge of the to-be processed body will be weakened and moved away, and thereby the steep plasma distribution at the edge of the to-be processed body will be moderated, and uniformity of in-plane film thickness of processing of the to-be processed body will be enhanced.

The ring-shaped dielectric is fixed to a boat on which the to-be processed body is mounted. The ring-shaped dielectric and the to-be processed body are disposed such that they are deviated from each other in a vertical direction in order to prevent the dielectric from interfering with a transfer tool when the to-be processed body is transferred.

Next, the first embodiment of the present invention will be explained in detail with reference to the drawings.

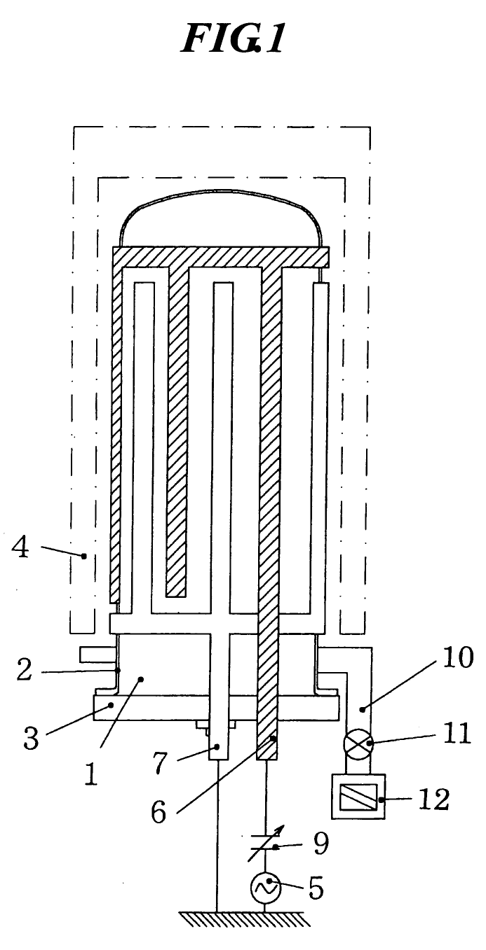

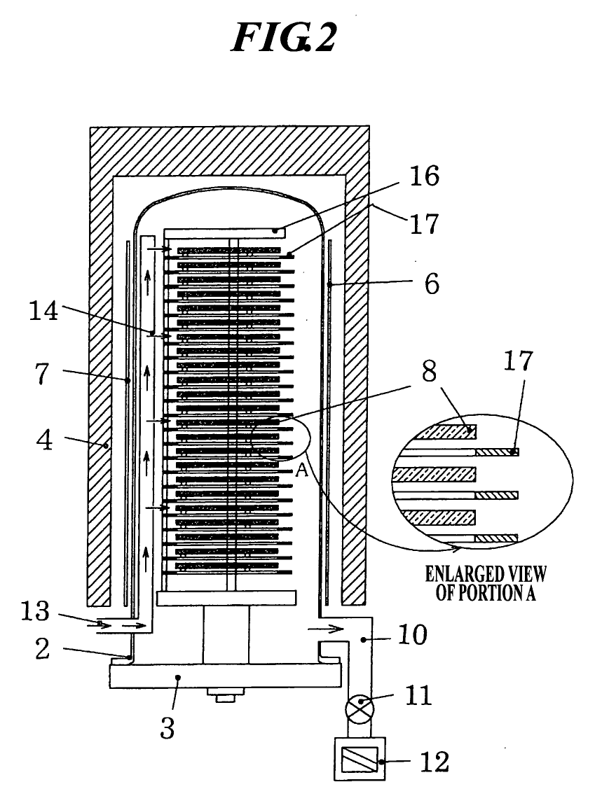

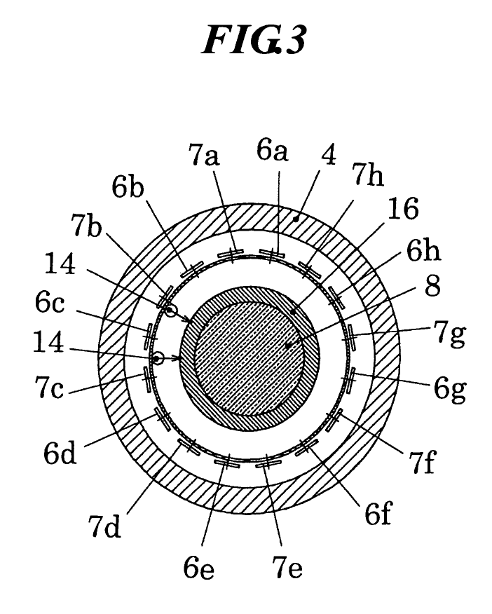

FIG. 1 is a schematic diagram for explaining a processing furnace of a plasma processing apparatus according to the first embodiment of the present invention. FIG. 1 is for explaining a structure of electrodes disposed on an outer surface of a reaction chamber 1. FIG. 2 is a schematic vertical sectional view for explaining the processing furnace of the plasma processing apparatus of the first embodiment of the present invention. FIG. 3 is a schematic transverse sectional view for explaining the processing furnace of the plasma processing apparatus of the first embodiment of the present invention.

The reaction chamber 1 is air-tightly closed by a reaction tube 2 and a seal cap 3. A heater 4 is provided around the reaction tube 2 so as to surround the reaction chamber 1. The reaction tube 2 comprises a dielectric such as quartz. A first electrode 6 is connected to a high-frequency power supply 5 and a second electrode 7 is electrically grounded. The first electrode 6 and the second electrode 7 are disposed on an outer circumference of the reaction tube 2. The electrode 6 includes stripe portions 6a to 6h, and the electrode 7 includes stripe portions 7a to 7h. The stripe portions 6a to 6h and the stripe portions 7a to 7h are alternately disposed such that they are perpendicular to a to-be processed body 8 such as a semiconductor silicon wafer. High-frequency (RF) alternating-current electric power, which is outputted from the high-frequency power supply 5, can be applied between the electrodes 6 and 7 through a matching device 9.

The reaction chamber 1 is connected to a pump 12 through an exhaust pipe 10 and a pressure control valve 11 so that gas in the reaction chamber 1 can be discharged. A gas-introduction port 13 is provided in the reaction chamber 1. The gas-introduction port 13 vertically stands along a sidewall of the reaction tube 2. A plurality of gas supply thin holes 14 are formed in the vertical portion, and sizes of the gas supply thin holes 14 are adjusted so that processing gas can equally be supplied in the height direction. Although only four gas supply thin holes 14 are shown in FIG. 2, a plurality of gas supply thin holes 14 are formed in the vertical portion of the gas-introduction port 13.

A ring boat 16 is provided in the reaction chamber 1. A plurality of semiconductor wafers, about 100 to 150, for example, can be loaded on the ring boat 16 one by one in a horizontal position so that the wafers as to-be processed bodies 8 can be processed at a time. Each wafer has a diameter of 200 mm, for example. The ring boat 16 is integrally formed with ring-shaped dielectrics 17. Each dielectric 17 is disposed in an outer circumference space of the to-be processed body 8, and the dielectric 17 is of a ring shape having a width of 10 to 40 mm. A quartz ring is preferably used as the ring-shaped dielectric 17.

The ring-shaped dielectrics 17 are provided with support sections, and the to-be processed bodies 8 are supported by the support sections, respectively. The ring-shaped dielectric 17 and the to-be processed body 8 are deviated from each other in the vertical direction.

Next, the operation of the apparatus will be explained.

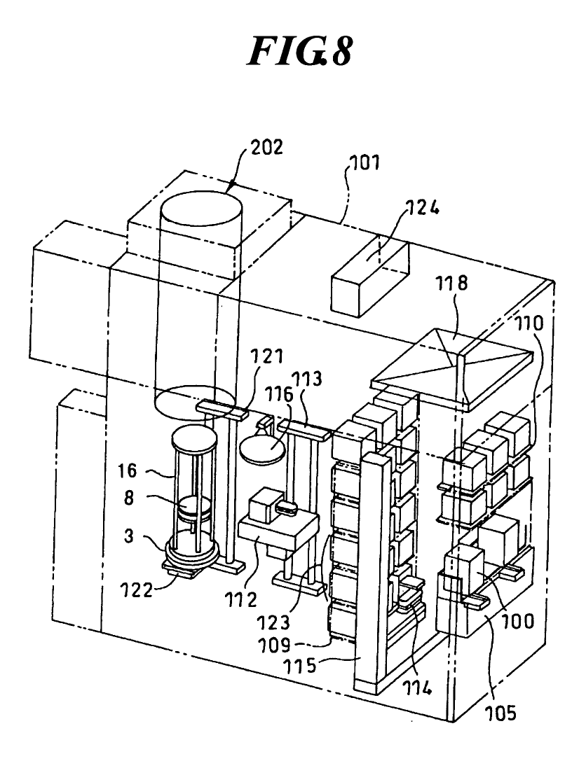

To load the to-be processed bodies 8 on the ring boat 16 by an elevator mechanism (see an elevator member 122 in FIG. 8) in a state where the reaction chamber 1 is under atmospheric pressure, the seal cap 3 is moved downward, a necessary number of to-be processed bodies 8 are loaded on the ring boat 16 by a to-be processed body transfer robot (see a wafer moving machine 112 in FIG. 8) and then, the seal cap 3 is moved upward and is inserted into the reaction chamber 1.

The heater 4 is turned ON so that members in the reaction chamber 1 such as to-be processed bodies 8 are heated to a predetermined temperature. When the to-be processed bodies are transferred, if the heater temperature becomes excessively low, much time is required for increasing the temperature in the reaction chamber to a predetermined value and stabilizing the state after the transfer of the to-be processed bodies 8 is completed. Therefore, the temperature is lowered to such a value that the transfer operation of the to-be processed bodies is not hindered, and the transfer operation is carried out in a state where the value is maintained.

Simultaneously, gas in the reaction chamber 1 is discharged from an exhaust port (not shown) through the exhaust pipe 10. When the temperature of the to-be processed bodies 8 reaches a predetermined value, reaction gas is introduced into the reaction chamber 1 from the gas-introduction port 13, the pressure in the reaction chamber 1 is maintained at a given value by the pressure control valve 11. If the pressure in the reaction chamber 1 becomes the predetermined value, AC electric power which is outputted from the high-frequency power supply 5 is supplied to the first electrode 6 through the matching device 9, the second electrode 7 is grounded and plasma is generated between the electrodes 6 and 7.

Since the ring-shaped dielectrics 17 are disposed around the to-be processed bodies 8, plasma having high energy at the edges of the to-be processed bodies 8 is moved away from the to-be processed bodies 8. Since only plasma having small energy and long lifetime substantially uniformly exists between to-be processed bodies 8, uniform film forming processing can be carried out on the to-be processed bodies 8. Since the ring-shaped dielectrics 17 and the to-be processed bodies 8 are deviated from each other in the vertical direction, the to-be processed bodies 8 can be transferred without largely modifying a transfer tool, which is used in the case of no ring-shaped dielectric 17.

### SECOND EMBODIMENT

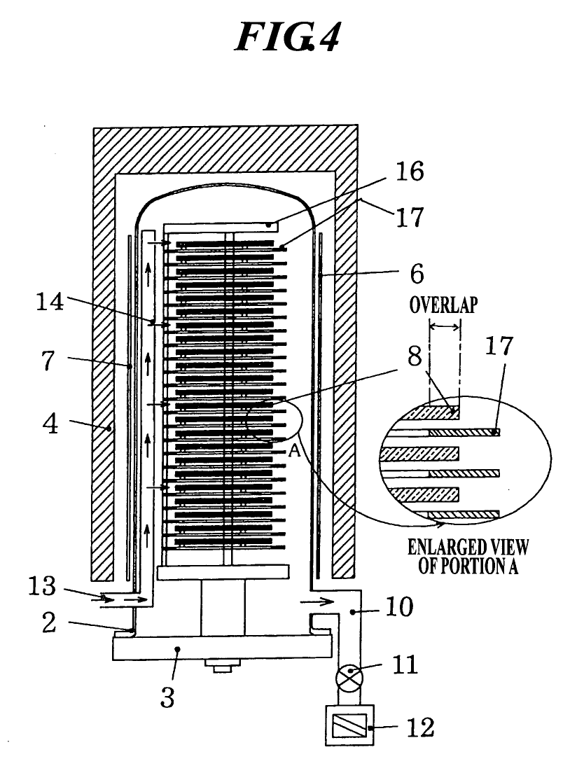

FIG. 1 is a schematic diagram for explaining a processing furnace of the plasma processing apparatus according to the second embodiment of the present invention, and is for explaining structures of the electrodes placed on the outer surface of the reaction chamber 1. FIG. 4 is a schematic vertical sectional view for explaining the processing furnace of the plasma processing apparatus of the second embodiment of the present invention. FIG. 3 is a schematic transverse sectional view for explaining the processing furnace of the plasma processing apparatus of the second embodiment of the present invention.

In the first embodiment, the semiconductor wafer having the diameter of 200 mm is used as the to-be processed body 8. In the second embodiment, a semiconductor wafer having a diameter of 300 mm will be used. In the first embodiment, an overlap range (overlap amount) where the outer circumferential end of the semiconductor wafer as the to-be processed body 8 and the inner circumferential end of the ring-shaped dielectric 17 overlap each other is 0 mm as viewed from the vertical direction. The second embodiment has three values of this overlap range, i.e., 0 mm, 10 mm and 20 mm. Other points of the second embodiment are the same as those of the first embodiment.

In the second embodiment, an effect of a case where the ring-shaped dielectric 17 is extended (0 mm, 10 mm, 20 mm) inside the semiconductor wafer as the to-be processed body 8 and the process processing (oxidation processing) is carried out will be explained.

When the overlap amount is 0 mm, a ring having a width of 17 mm is used as the dielectric 17. When the overlap amount is 10 mm, a ring having a width of 27 mm is used as the dielectric 27. When the overlap amount is 20 mm, a ring having a width of 37 mm is used as the dielectric 17.

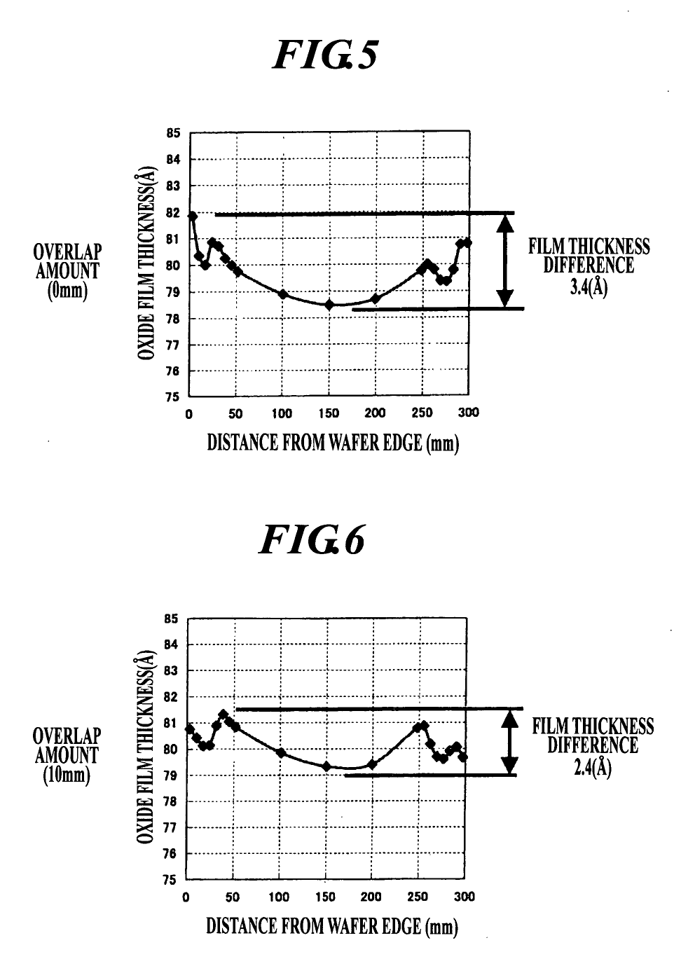

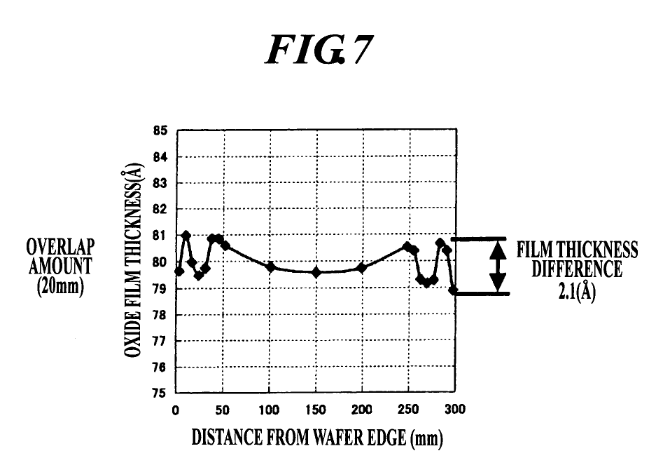

The diameter of the to-be processed body 8 is 300 mm. Examples of oxide film thickness distributions shown in FIGS. 5 to 7 show a cross section of the diameter of the to-be processed body 8. Processing conditions in the second embodiment are as follows: processing gas is oxygen and hydrogen, pressure is 35 Pa, temperature is 900° C., RF electric power is 1 KW, and time is 8.5 minutes. FIGS. 5 to 7 show oxide film thickness distributions when the overlap amount between the semiconductor wafer as the to-be processed body 8 and the ring-shaped dielectric 17 is 0 mm, 10 mm and 20 mm, respectively.

According to FIGS. 5 to 7, a difference in film thickness (maximum-minimum) is smaller when the overlap amount is 20 mm as compared with 10 mm. Moreover, the maximum value and the minimum value of the film thickness exist around the to-be processed body 8. Therefore, it can be considered that if the ring-shaped dielectric 17 and the semiconductor wafer as the to-be processed body 8 overlap each other by 20 mm, optimal process processing uniformity can be obtained under the above-mentioned processing conditions. If the overlap amount between the ring-shaped dielectric 17 and the semiconductor wafer is obtained in accordance with the processing conditions in this manner, it is possible to provide the optimal hardware.

Next, an outline of the plasma processing apparatus of the first embodiment and the second embodiment of the present invention will be explained with reference to FIG. 8. FIG. 8 is a schematic perspective view for explaining the plasma processing apparatus of the first embodiment and the second embodiment of the present invention.

A cassette stage 105 as a holder delivery member, which transfers cassette 100 as a substrate accommodation container to and from an external transfer device, is provided in a casing 101 on the front surface side. A cassette elevator 115 as elevator means is provided behind the cassette stage 105. A cassette moving machine 114 as transfer means is mounted on the cassette elevator 115. Cassette shelves 109 as mounting means of the cassettes 100 are provided behind the cassette elevator 115. Auxiliary cassette shelves 110 are provided above the cassette stage 105. A clean unit 118 is provided above the auxiliary cassette shelves 110 so that clean air flows through the casing 101.

A processing furnace 202 is provided above a rear portion of the casing 101. A boat elevator 121 as elevator means is provided below the processing furnace 202. The boat elevator 121 vertically moves the ring boat 16 as substrate holding means to the processing furnace 202. The ring boat 16 hold wafers 5 as substrates in horizontal attitude in multistage manner. A seal cap 3 as a lid is attached to the tip of the elevator member 122 which is attached to the boat elevator 121, and the seal cap 3 vertically supports the ring boat 16. A transfer elevator 113 as elevator means is provided between the boat elevator 121 and the cassette shelves 109. A wafer moving machine 112 as transfer means is attached to the transfer elevator 113. A furnace opening shutter 116 as closing means is provided beside the boat elevator 121. The furnace opening shutter 116 has an opening/closing mechanism and air-tightly closes a wafer carrying in/out port 131, which is located in the lower end of the processing furnace 202.

The cassette 100, into which wafers 5 are loaded, is carried onto the cassette stage 105 from the external transfer device (not shown) such that the wafers 5 are oriented upward, and the cassette 100 is rotated 90 degrees on the cassette stage 105 such that the wafers 5 are in their horizontal postures. The cassette 100 is transferred from the cassette stage 105 to the cassette shelves 109 or the auxiliary cassette shelves 110 in cooperation with vertical motion and lateral motion of the cassette elevator 115 and forward and backward motions and rotation of the cassette moving machine 114.

The cassette shelves 109 include transfer shelves 123 on which the cassettes 100 to be transferred by the wafer moving machine 112 are placed. The cassette 100, which contains the wafers 5 to be transferred, is transferred to the transfer shelf 123 by the cassette elevator 115 and the cassette moving machine 114.

When the cassette 100 is transferred to the transfer shelf 123, the wafers 5 in the cassette 100 are transferred to a boat 22, which is in the lower state, from the transfer shelf 123 in cooperation with forward and backward motions and rotation of the wafer moving machine 112 and vertical motion of the transfer elevator 113.

When a predetermined number of wafers 5 are transferred to the boat 22, the ring boat 16 is inserted into the processing furnace 202 by the boat elevator 121, and the processing furnace 202 is air-tightly closed by the seal cap 3. The wafers 5 are heated in the air-tightly closed processing furnace 202, processing gas is supplied into the processing furnace 202, and the wafers 5 are processed.

When the processing of the wafers 5 is completed, the wafers 5 are transferred to the cassette 100 on the transfer shelves 123 from the ring boat 16 in the reverse procedure to that described above, the cassette 100 is transferred to the cassette stage 105 from the transfer shelves 123 by the cassette moving machine 114, and is carried out from the casing 101 by the external transfer device (not shown).

When the ring boat 16 is lowered, the furnace opening shutter 116 air-tightly closes the wafer carrying in/out port 131 of the processing furnace 202 so as to prevent outside air from being mixed into the processing furnace 202.

The transfer operation by the cassette moving machine 114 is controlled by transfer operation control means 124.

### THIRD EMBODIMENT

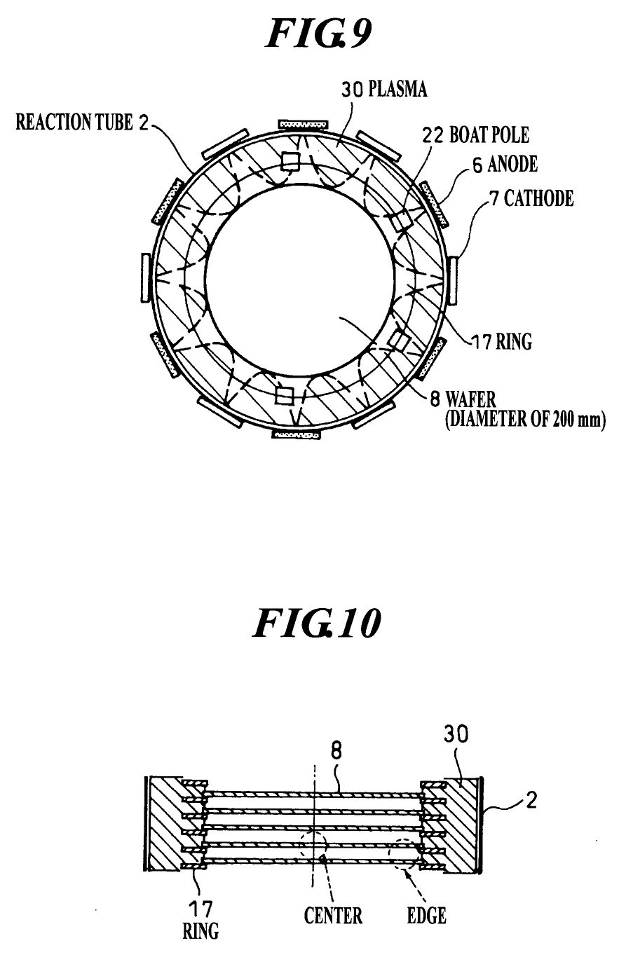

FIGS. 9 and 10 are a schematic transverse sectional view and a schematic vertical sectional view of a distribution state of plasma when the ring-shaped dielectric 17 is provided, respectively. FIGS. 9 and 10 are presented to make it easy to understand the distribution state. By providing the ring-shaped dielectric 17, an obstruction can be formed near the edge of a wafer, the edge region having high wafer density, and plasma in that region can be weakened. Therefore, it is possible to prevent the steep film thickness distribution from being generated around the wafer edge.

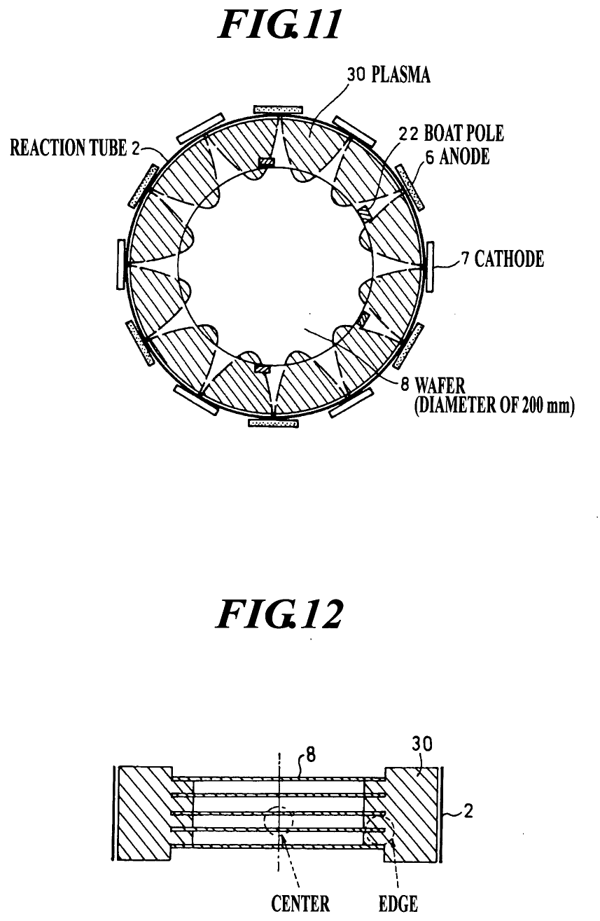

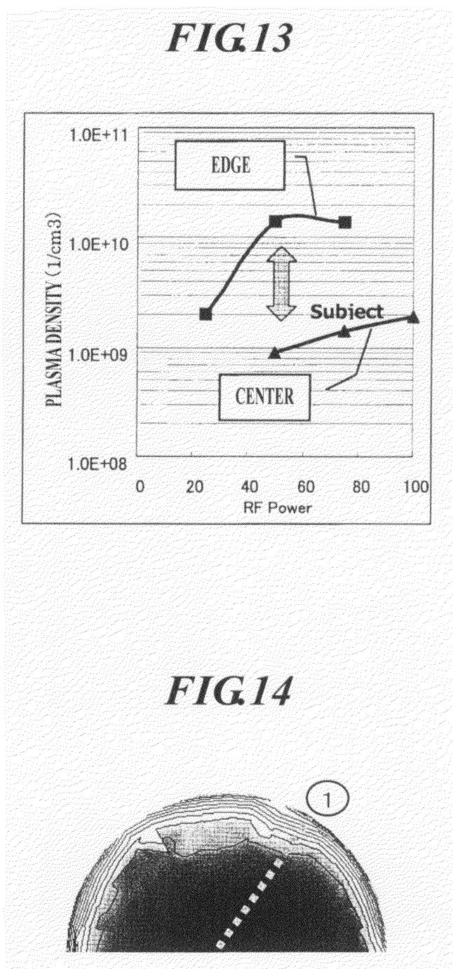

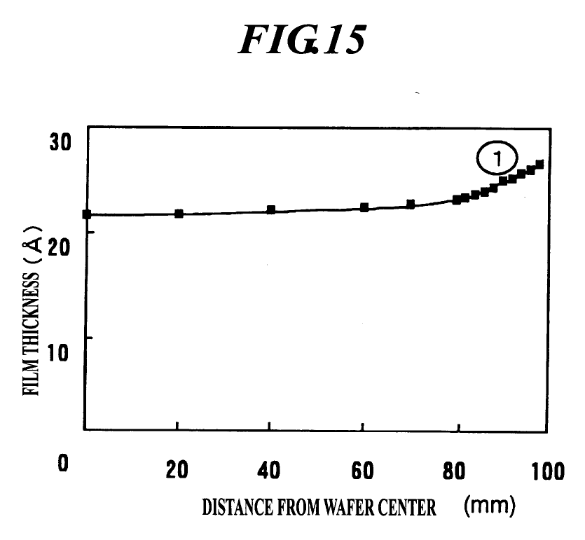

FIGS. 11 and 12 are a schematic transverse sectional view and a schematic vertical sectional view of a distribution state of plasma when the ring-shaped dielectric 17 is not provided, respectively. FIGS. 11 and 12 are presented to make it easy to understand the distribution state. Plasma is generated mainly between the wafer 8 and the reaction tube 2, and is diffused from the wafer edge. Therefore, plasma distribution becomes nonuniform on the surface of the wafer. Accordingly, a difference in plasma density between the wafer edge and the wafer center is increased as shown in FIG. 13.

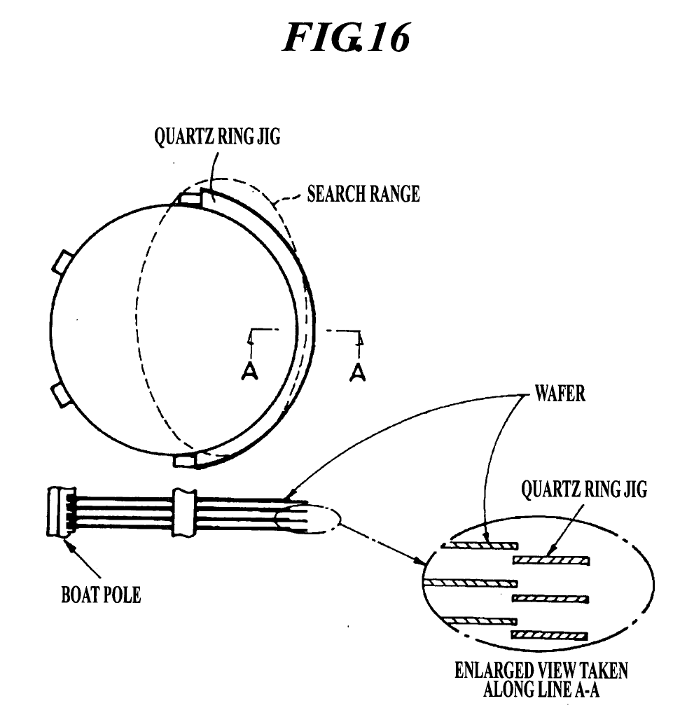

FIG. 14 is a diagram showing a film thickness distribution on a wafer when the ring-shaped dielectric 17 is not provided. FIG. 15 is a diagram showing a film thickness of the wafer 8 in its radial direction (1) when the ring-shaped dielectric 17 is not provided. It can be found that the film thickness is increased steeply in a range of about 20 mm of the wafer edge. The film forming conditions are as follows: H₂ and O₂ are used as processing gas, H₂ concentration is 85%, O₂ concentration is 15%, pressure is 60 Pa, temperature is 800° C., RF electric power is 1 kW, and time is 8.5 minutes.

FIGS. 16 to 18 are diagram for explaining an influence on a film thickness distribution which is varied depending upon the absence or presence of the ring-shaped dielectric 17. A semiconductor wafer having a diameter of 200 mm is used. As shown in FIG. 16, a half ring is used as the ring, and a quartz ring is provided only on a portion corresponding to the half of the semiconductor wafer. A width of the ring is 10 mm. The overlap amount between the semiconductor wafer and the quartz ring is 0 mm. The film forming conditions are as follows: H₂ and O₂ are used as processing gas, H₂ concentration is 85%, O₂ concentration is 15%, pressure is 60 Pa, temperature is 800° C., RF electric power is 1 kW, and time is 8.5 minutes.

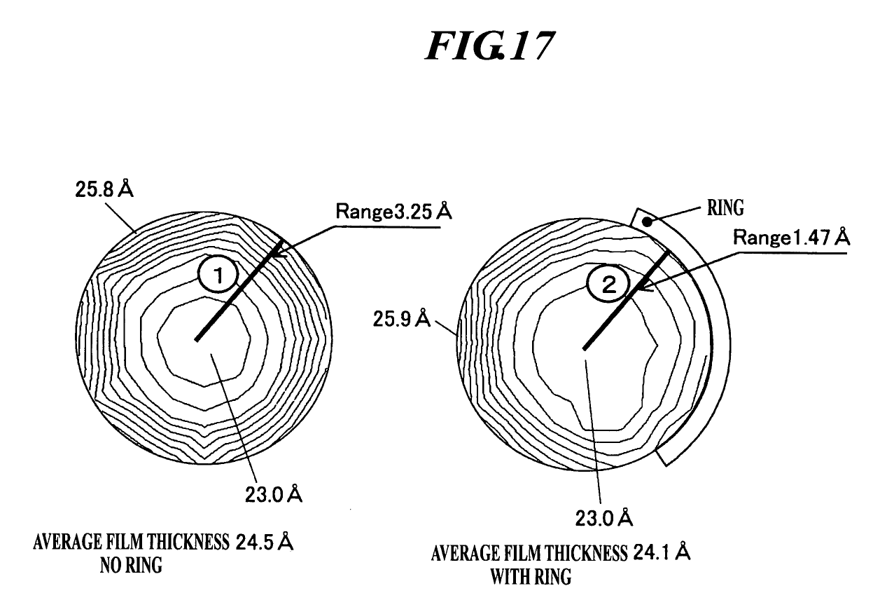

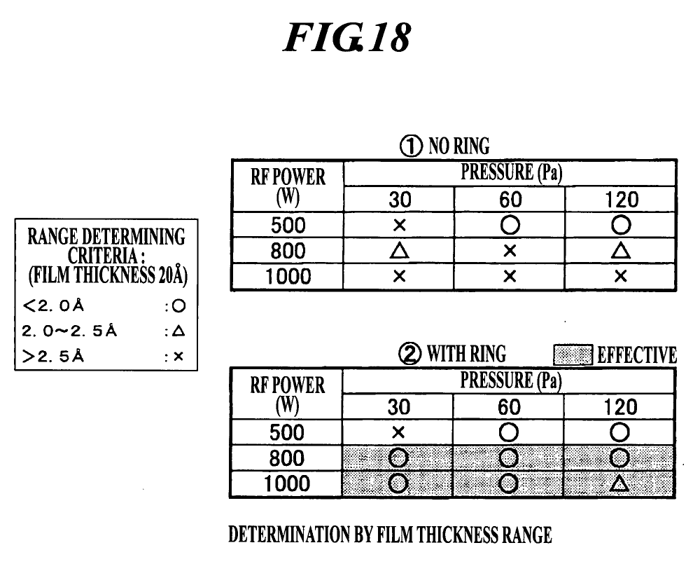

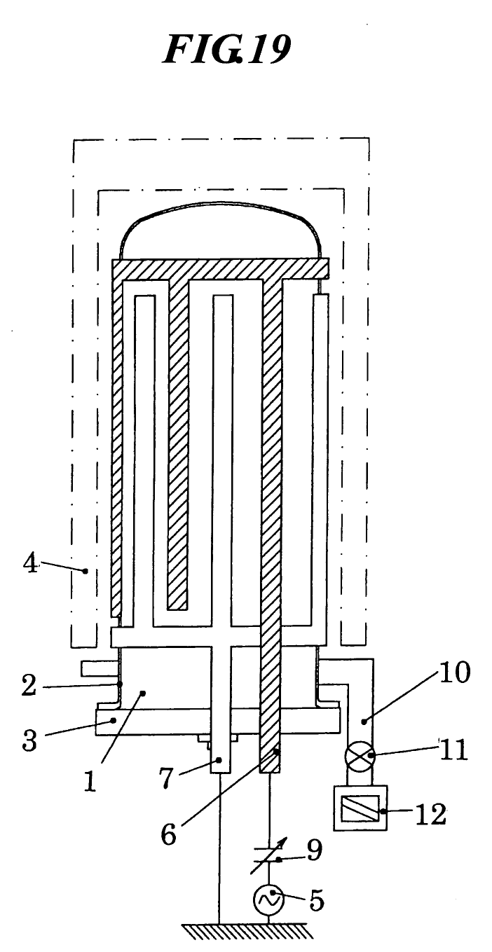

FIG. 17 shows a film thickness distribution. FIG. 18 is a diagram showing an improvement effect of the film thickness distribution by the quartz ring. According to FIGS. 17 and 18, it can be found that if the quartz ring is provided, the film thickness distribution on the surface of the wafer is improved.

Next, comparative examples will be explained with reference to FIGS. 19 to 21.

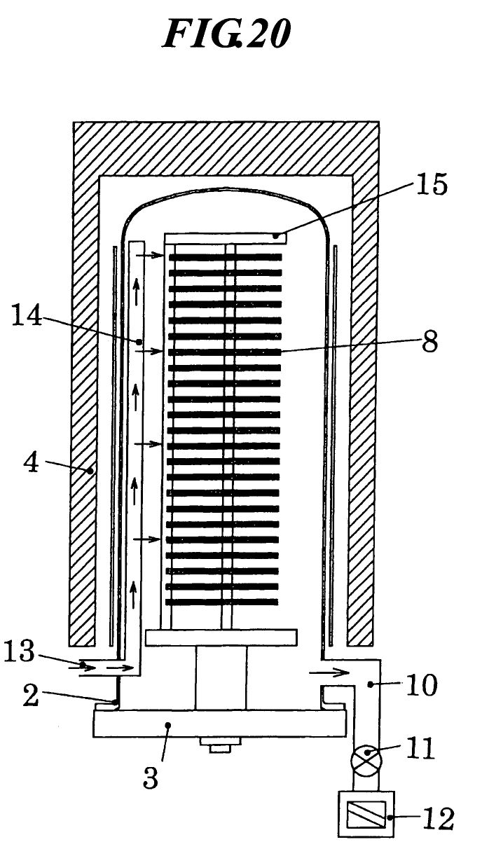

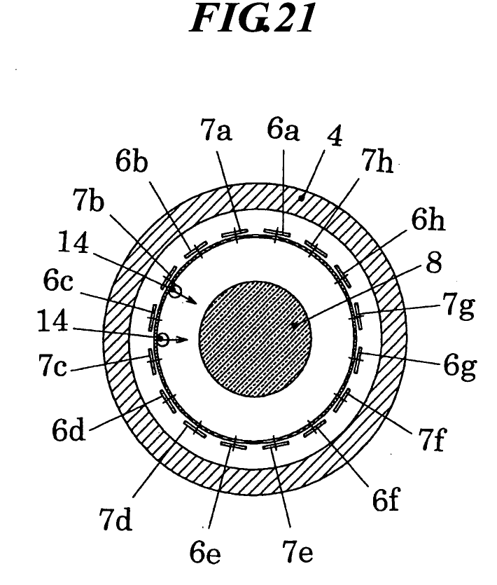

FIG. 19 is a schematic diagram for explaining a processing furnace of a plasma processing apparatus for comparison. FIG. 19 is for explaining structures of electrodes mounted on the outer surface of a reaction chamber 1. FIGS. 20 and 21 are a schematic vertical sectional view and a schematic transverse sectional view for explaining the processing furnace of the plasma processing apparatus for comparison, respectively.

The reaction chamber 1 is air-tightly closed by a reaction tube 2 and a seal cap 3. A heater 4 is provided around the reaction tube 2 so as to surround the reaction chamber 1. The reaction tube 2 comprises a dielectric such as quartz. A first electrode 6 is connected to a high-frequency power supply 5 and a second electrode 7 is electrically grounded. The first electrode 6 and the second electrode 7 are disposed on an outer circumference of the reaction tube 2. The first electrode 6 and the second electrode 7 are alternately disposed in a stripe form such that they are perpendicular to a to-be processed electrode body 8. High-frequency alternating-current electric power, which is outputted from the high-frequency power supply 5, can be applied between the electrodes 6 and 7 through a matching device 9. The reaction chamber 1 is connected to a pump 12 through an exhaust pipe 10 and a pressure control valve 11 so that gas in the reaction chamber 1 can be discharged. A gas-introduction port 13 is provided in the reaction chamber 1. A plurality of gas supply thin holes 14 are formed in an inner surface of the reaction chamber 1, and sizes of the gas supply thin holes 14 are adjusted so that processing gas can equally be supplied in the height direction.

A ring boat 15 is provided in the reaction chamber 1. A plurality of semiconductor wafers, about 100 to 150, for example, can be loaded on the ring boat 15 one by one in a horizontal position so that the wafers as to-be processed bodies 8 can be processed at a time. The to-be processed bodies 8 are supported by a large number of grooves formed in poles of the boats 15.

When the pressure in the reaction chamber 1 becomes a predetermined value, alternating-current electric power, which is outputted from the high-frequency power supply 5, is supplied to the first electrode 6 through the matching device 9, the second electrode 7 is grounded and plasma is generated between the electrodes. The to-be processed body 8 is processed by the generated plasma.

Since the electrodes 6 and 7 are disposed on the outer circumference of the reaction tube 1, plasma is generated mainly in a space between the reaction tube 2 and the to-be processed body 8. Therefore, there arises a problem that the processing speed at an edge of the to-be processed body is extremely accelerated owing to influence of a factor having high energy and short lifetime, and the uniformity of the in-plane film thickness in process treatment is extremely deteriorated. This phenomenon more strongly appears under the condition that high-frequency output is increased and the density is high.

The entire disclosures of Japanese Patent Application No. 2005-132706 filed on Apr. 28, 2005 and Japanese Patent Application No. 2005-280164 filed on Sep. 27, 2005 each including specification, claims, drawings and abstract are incorporated herein by reference in their entireties so far as the national law of any designated or elected State permits in this international application.

Although various exemplary embodiments have been shown and described, the invention is not limited to the embodiments shown. Therefore, the scope of the invention is intended to be limited solely by the scope of the claims that follow.

### INDUSTRIAL APPLICABILITY

As explained above, according to the preferred embodiments of the present invention, it is possible to solve a problem of nonuniformity in-plane treatment of plasma caused by influence of strong plasma which is generated at an edge of a to-be processed body, and it is possible to uniformly carry out the in-plane treatment of the to-be processed body.

As a result, the invention can suitably be utilized for a substrate processing apparatus which processes a substrate such as a semiconductor wafer using plasma generated by high-frequency electric power, and for a producing method of a semiconductor device.

1. A substrate processing apparatus, comprising:
a reaction tube to accommodate at least one substrate;
at least a pair of electrodes disposed outside the reaction tube; and
a dielectric member, wherein
a plasma generation region is formed at least in a space between an inner wall of the reaction tube and an outer circumferential edge of the substrate,
the dielectric member including a main face extending in a radial direction of the substrate and in a substantially entire circumferential direction of the substrate in a horizontal plane parallel to a main face of the substrate, and is disposed in an outer circumferential region of the substrate, and
gas activated in the plasma generation region is supplied through a surface region of the main face of the member to the substrate.

2. The substrate processing apparatus according to claim 1, wherein the member is a ring-shaped flat plate.

3. The substrate processing apparatus according to claim 1, wherein the main face of the member and the main face of the substrate are disposed on different horizontal planes in a vertical direction with respect to the main face of the substrate.

4. The substrate processing apparatus according to claim 3, wherein a second substrate is also to be accommodated in the reaction tube,
the first and second substrates are to be stacked such that main faces of the substrates overlap each other with a space therebetween in a vertical direction with respect to the main faces, and
the member is to be located between the first and second substrates.

5. The substrate processing apparatus according to claim 4, wherein at least a portion of the main face of the member extends toward a center side of the substrate from the outer circumferential edge of the substrate, and the portion of the main face of the member is overlapped with a portion of the substrate as viewed from the vertical direction.

6. A producing method of a semiconductor device, providing a substrate processing apparatus including:
a reaction tube to accommodate at least one substrate;
at least a pair of electrodes disposed outside the reaction tube; and
a dielectric member having a main face extending in a radial direction of the substrate and in a substantially entire circumferential direction of the substrate in a horizontal plane parallel to a main face of the substrate, the member being disposed in an outer circumferential region of the substrate;
generating plasma at least in a space between an inner wall of the reaction tube and an outer circumferential edge of the substrate;
activating processing gas with the plasma;
supplying the activated gas through a surface region of the main face of the member to the substrate; and
subjecting the substrate to a desired processing using the processing gas which has been passed through the surface region.
